(19) United States
(12) Patent Application Publication
(10) Pub. No.: US 2002/0096726 A1
(43) Pub. Date: Jul. 25, 2002

(54) Semiconductor device and manufacturing method thereof

(75) Inventor: Hidetoshi Koike, Yokohama-shi (JP)

Correspondence Address: FOLEY AND LARDNER, SUITE 500, 3000 K STREET NW, WASHINGTON, DC, 20007, US

(73) Assignee: KABUSHIKI KAISHA TOSHIBA

(21) Appl. No.: 10/023,850

(22) Filed: Dec. 21, 2001

(30) Foreign Application Priority Data
Dec. 26, 2000 (JP) 2000-394587

(51) Int. Cl. H01L 31/062

(52) U.S. Cl. 257/384

(57) ABSTRACT

A semiconductor device has a diffused layer provided on a surface portion of a silicon substrate; an insulating layer provided on the diffused layer and formed with a contact hole at a portion provided with a contact; and a suicide layer provided within said contact hole as a bottom portion of the contact so as to come into contact with the diffused layer, the suicide layer having its bottom surface being flush with or higher than the surf ace of the silicon substrate. And a semiconductor device manufacturing method includes: providing a thin oxide layer and a gate on the surface of a silicon substrate; providing a diffused layer service as a source/drain on the surface of the silicon substrate; depositing an insulating layer on the whole and forming a contact hole in the insulating layer and the thin oxide layer so that the diffused layer is exposed; depositing a thin silicon film on the whole; depositing a barrier metal on the thin silicon film; and making the barrier metal react on the thin silicon film by effecting a thermal treatment and thus providing a silicide layer.

### CROSS REFERENCE TO RELATED APPLICATIONS

This application is based upon and claims the benefit of priority from the prior Japanese Patent Applications No. 2000-394587, filed on Dec. 26, 2000, the entire contents of which are incorporated herein by reference.

### BACKGROUND OF THE INVENTION

The present invention relates generally to a semiconductor device and a manufacturing method thereof, and more particularly to a technology of forming a diffused layer contact of a memory cell.

It is a general technique for the semiconductor device that a silicide layer of TiSi and CoSi is provided on the upper surface of a source/drain diffused layer in order to reduce a contact resistance to the source/drain diffused layer.

FIGS. 3A through 3E are sectional views for explaining on a process-by-process basis an example in which a contact process according to the prior art is applied to a DRAM cell.

To start with, as shown in FIG. 3A, an element isolation region 2 is provided on a p-type silicon substrate 1 by a known STI (Shallow Trench Isolation) method, and a gate oxide film 3 is provided on the entire surface by a thermal oxidation method. Polysilicon is then deposited on this gate oxide film 3, and a gate electrode 4 of a transistor is formed by patterning the gate oxide film and the polysilocon layer. Thereafter, an n-type diffused layer 5 is formed in self-alignment manner to a depth of, e.g., 100 nm by an ion implantation of impurity such as phosphorus, arsenic and so on.

Next, as shown in FIG. 3B, an inter-layer insulating layer 6 composed of BPSG on the order of, e.g., 700 nm is deposited by use of a CVD (Chemical vapor Deposition) method, etc., Thereafter, the inter-layer insulating layer 6 is etched by an RIE (Reactive Ion Etching) method as well as by a photolithography method, thereby forming a contact hole 7 down to the diffused layer 5.

Next, as shown in FIG. 3C, a barrier metal such as Ti is deposited by a sputtering method, etc., and a barrier metal layer 8 of 20 nm thick is provided on the exposed diffused layer 5.

Subsequently, as shown in FIG. 3D, a thermal treatment is executed at a temperature of 600° C., and then the barrier metal layer 8 reacts on silicon of the diffused layer 5 brought into contact with this layer's, with the result that a silicide layer 9 composed of TiSi is provided. At this time, TiSi is generated at a Ti-to-Si thickness ratio of 1:12.27, and hence the silicide layer 9 is formed to the depth of 45 nm from the surface of the p-type silicon substrate 1.

Finally, as shown in FIG. 3E, for example, tungsten W is deposited up to a thickness of 40 nm on the entire surface by the CVD method to fill the contact hole 7 with tungsten W, and the surface is completely flattened by a CMP (Chemical-Mechanical Polishing) method, thereby providing a W plug 10.

As the structure becomes more hyperfine, if the depth of the diffused layer becomes as shallow as 100 nm, a distance from an interface between the diffused layer and the silicon substrate to the bottom surface of the silicide layer gets extremely short.

FIGS. 4A and 4B are schematic views for explaining such a state. Supposing that the depth of the diffused layer is 100 nm and that the depth of the suicide layer is 45 nm as in the prior art described above, the distance from the interface between the diffused layer and the silicon substrate to the silicide layer is only 55 nm. If the distance from the interface between the diffused layer and the silicon substrate to the suicide layer thus decreases, it is known that there appear a dispersion in the thickness of the suicide layer and a locally deep silicide layer called a spike 11 penetrating the diffused layer with the result that a junction leakage of the diffused layer occurs (FIG. 5).

Thus, a problem inherent in the prior art is that the junction leakage of the diffused layer occurs due to the formation of the silicide layer, and a data retaining characteristic of the memory cell declines.

Therefore, especially the memory cell of the DRAM and so on is not formed with such a self-aligned silicide (SALICIDE) layer that the silicide layer composed of TiSi and CoSi usually used for a logic area is provided over the entire surface of the source/drain diffused layer, however, if the contact such as the W plug and so forth is formed in the diffused layer containing no SALICIDE layer, there arises a problem in which a new junction leakage of the diffused layer occurs.

### SUMMARY OF THE INVENTION

A semiconductor device according to the one embodiment of present invention comprises:

a diffused layer provided on a surface portion of a silicon substrate;

an insulating layer provided on said diffused layer and formed with a contact hole at a portion provided with a contact; and

a silicide layer provided within said contact hole as a bottom portion of said contact so as to come into contact with said diffused layer, said silicide layer having its bottom surface being flush with or higher than the surface of said silicon substrate.

A semiconductor device according to another embodiment of the present invention comprises:

a diffused layer provided on a surface portion of a silicon substrate;

an insulating layer provided on said diffused layer and formed with a contact hole at a portion provided with a contact; and

a silicide layer provided within said contact hole as a bottom portion of said contact so as to come into contact with said diffused layer, said silicide layer having its bottom surface being lower than the surface of said silicon substrate,

wherein a distance from the surface of said silicon substrate to the bottom surface of said silicide layer is equal to or smaller than ½ a thickness of said suicide layer provided as the bottom portion of said contact.

A method for manufacturing a semiconductor device according to an embodiment of the present invention comprises:

providing a thin oxide layer and a gate on the surface of a silicon substrate;

providing a diffused layer service as a source/drain on the surface of said silicon substrate;

depositing an insulating layer on the whole and forming a contact hole in said insulating layer and said thin oxide layer so that said diffused layer is exposed;

depositing a thin silicon film on the whole;

depositing a barrier metal on said thin silicon film; and

a step of making said barrier metal react on said thin silicon film by effecting a thermal treatment and thus providing a silicide layer.

A method for manufacturing a semiconductor device according to further embodiment of the present invention comprises:

providing a thin oxide layer and a gate on the surface of a silicon substrate;

providing a diffused layer service as a source/drain on the surface of said silicon substrate;

depositing a barrier metal on the whole;

depositing a thin silicon film on said barrier metal; and

making said barrier metal react on said thin silicon film by effecting a thermal treatment and thus providing a silicide layer.

### BRIEF DESCRIPTION OF THE DRAWINGS

In the accompanying drawings;

FIGS. 1A to 1F are sectional views showing on a process-by-process basis a method of manufacturing a semiconductor device in a first embodiment of the present invention;

FIGS. 2A to 2F are sectional views showing on the process-by-process basis the method of manufacturing the semiconductor device in a second embodiment of the present invention;

FIGS. 3A to 3C are sectional views showing on the process-by-process basis a manufacturing method in which a contact process according to the prior art is applied to a DRAM cell;

FIGS. 4A and 4B are schematic views for explaining a problem inherent in the prior art; and

FIG. 5 is a schematic view for explaining a spike.

### DETAILED DESCRIPTION OF THE INVENTION

Some embodiments of the present invention will hereinafter be described in depth with reference to the accompanying drawings.

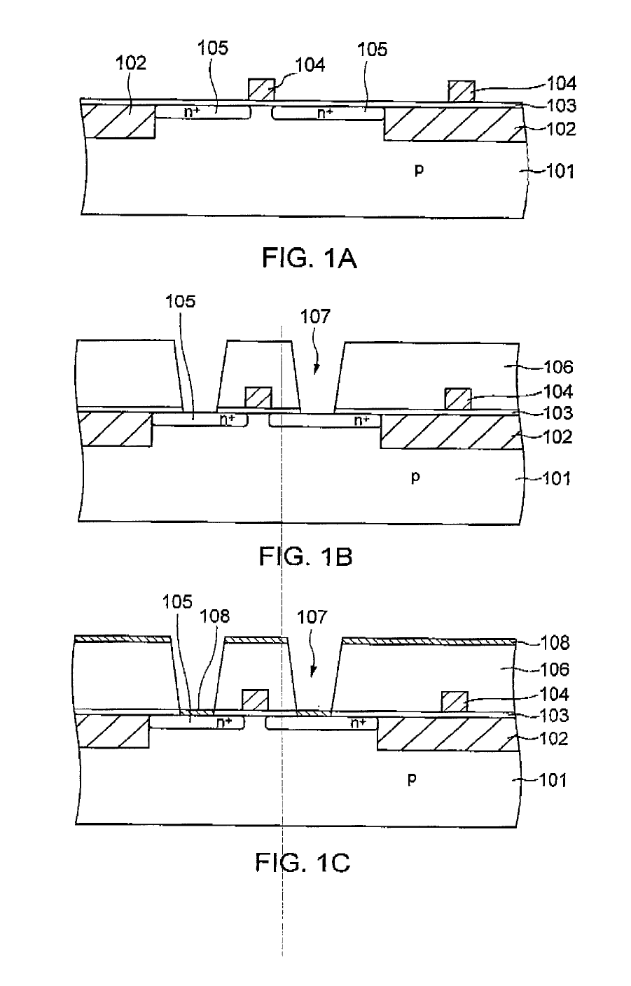

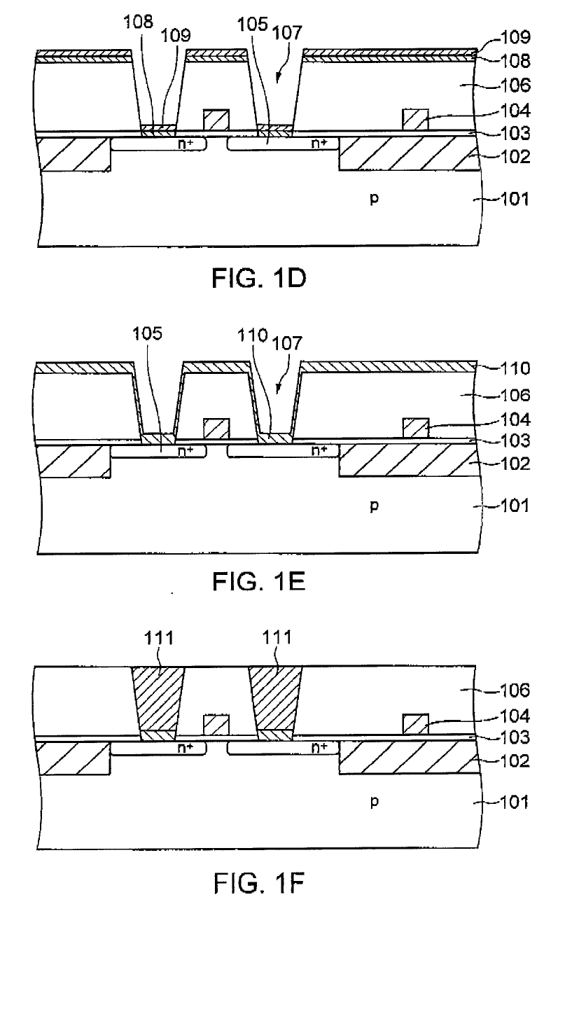

FIGS. 1A to 1F are sectional views of a semiconductor device, showing on a process-by-process basis a method of manufacturing the semiconductor device in a first embodiment of the present invention, wherein this manufacturing method is applied to a DRAM cell.

To begin with, as shown in FIG. 1A, an element isolation region 102 is provided on a p-type silicon substrate 101 by the STI method , etc., and a gate oxide film 103 is provided on the whole by a thermal oxidation method. Polysilicon is then deposited on this gate oxide film 103 by a CVD method, and a gate electrode 104 of a transistor is formed by patterning using the photolithography. Thereafter, an n-type diffused layer 105 is formed in self-alignment with the gate electrode 104 to a depth of, e.g., 100 nm by an ion implantation of impurity such as phosphorus, arsenic and so on.

Next, as shown in FIG. 1B, an inter-layer insulating layer 106 composed of BPSG on the order of, e.g., 700 nm is deposited by use of the CVD method, etc. Thereafter, the inter-layer insulating layer 106 is , etched to such an extent that the diffused layer 104 gets exposed by an RIE method as well as by a photolithography process, thereby forming a contact hole 107 down to the diffused layer 105.

Next, as shown in FIG. 1C, a thin silicon film 108 composed of, e.g., polysilicon or amorphous silicon is deposited up to a thickness of 45 nm on the entire surface by the CVD method, etc.

In particular, amorphous silicon among the silicon materials to be deposited is a preferable material because it can be deposited at a low temperature.

Subsequently, as shown in FIG. 1D, a barrier metal such as Ti is deposited by a sputtering method, etc., and a barrier metal layer 109 that is 20 nm thick is provided on the thin silicon film 108.

Next, a thermal treatment is executed at a temperature of, e.g., 600° C., a barrier metal 109 reacts on silicon contained in the thin silicon film 108 brought into contact with this metal 109, with the result that a silicide layer 110 composed of TiSi is provided as shown in FIG. 1E.

At this time, TiSi is generated at a Ti-to-Si thickness ratio of 1: 2.27, and hence an interface with the silicide layer 210 is formed on the surface of the p-type silicon substrate 101. Namely, silicon is extracted from the silicon layer deposited beforehand on the barrier metal diffused layer when forming silicide, and therefore it does not happen that the silicide layer if provided under the p-type silicon substrate.

Finally, as shown in FIG. 1F, for example, tungsten w is deposited up to a thickness of 400 nm on the whole by the CVD method, etc., to fill the contact hole 7 with tungsten W, and the surface is completely flattened by a CMP method, etc., thereby providing a W plug 111.

In the thus formed contact, the lowest portion of the silicide layer that is provided on the bottom of the contact is flush with or higher than the surface of the silicon substrate. Accordingly, the distance from the interface between the diffused layer and the silicon substrate to the suicide layer can be kept long, and it is therefore possible to prevent a junction leakage of the diffused layer due to a dispersion in the thickness of the silicide layer and to the formation of the locally deep silicide layer called a spike.

Further, according to the method in the first embodiment, the thin silicon film and the barrier metal are sequentially deposited on the diffused layer exposed after forming the contact hole down to the diffused layer, and the silicide layer is provided by effecting the thermal treatment thereafter. Silicon needed for forming silicide is extracted from the thin silicon film, the bottom surface of silicide is not in close proximity to the interface between the diffused layer and the silicon substrate, and the sufficiently long distance can be kept. It is therefore feasible to prevent the junction leakage of the diffused layer due to the dispersion in the thickness of the silicide layer and to the formation of the locally deep silicide layer called the spike.

Note that if the thickness of the thin silicon film provided on the bottom of the contact hole is small, a quantity of silicon extracted from the thin silicon film when forming silicide is deficient, and silicon might be supplied from the diffused layer thereunder in the first embodiment. In this case, the bottom surface of the silicide layer formed is lower than the surface of the silicon substrate, however, if a distance from the surface of the silicon substrate to the bottom surface of the silicide layer is equal to or smaller than ½ the thickness of the silicide layer, the occurrence of the leakage can be restrained. Hence, the thickness of the thin silicon film can be determined so as to meet this condition.

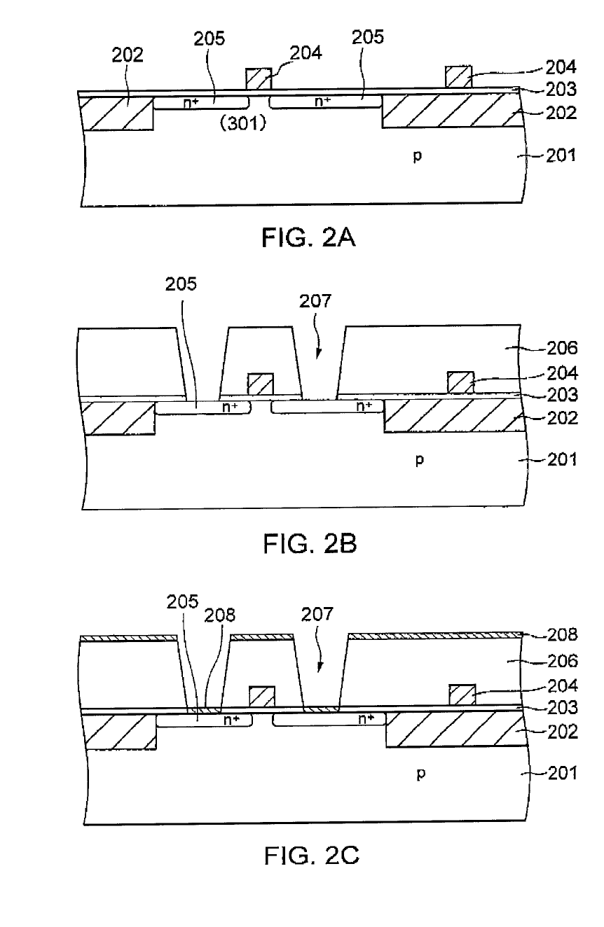

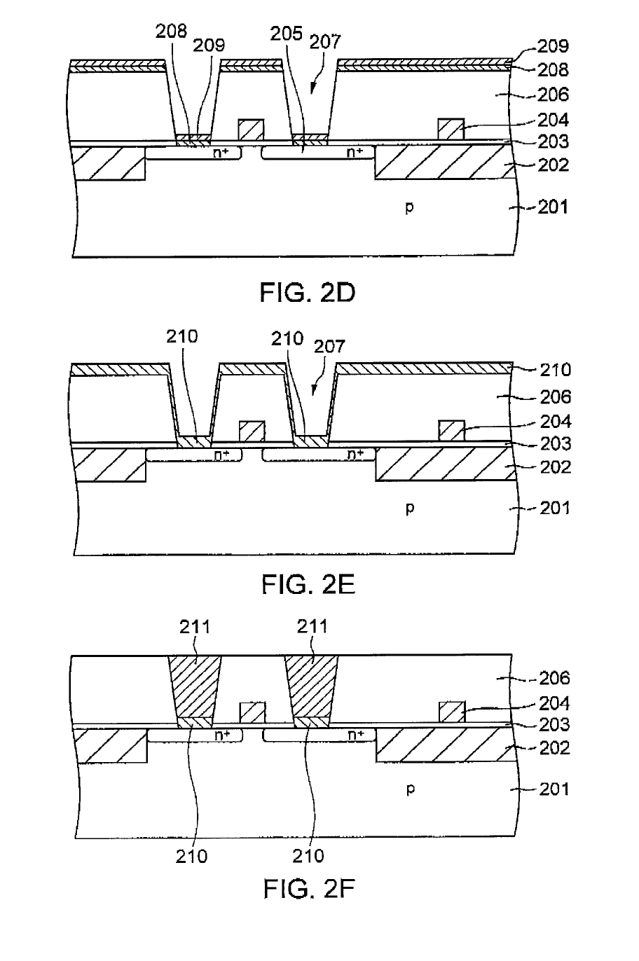

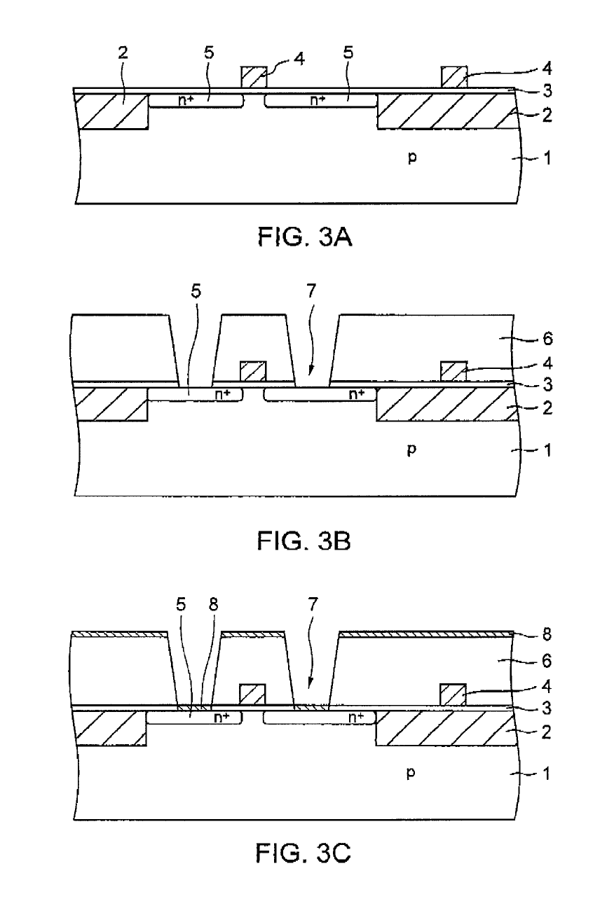

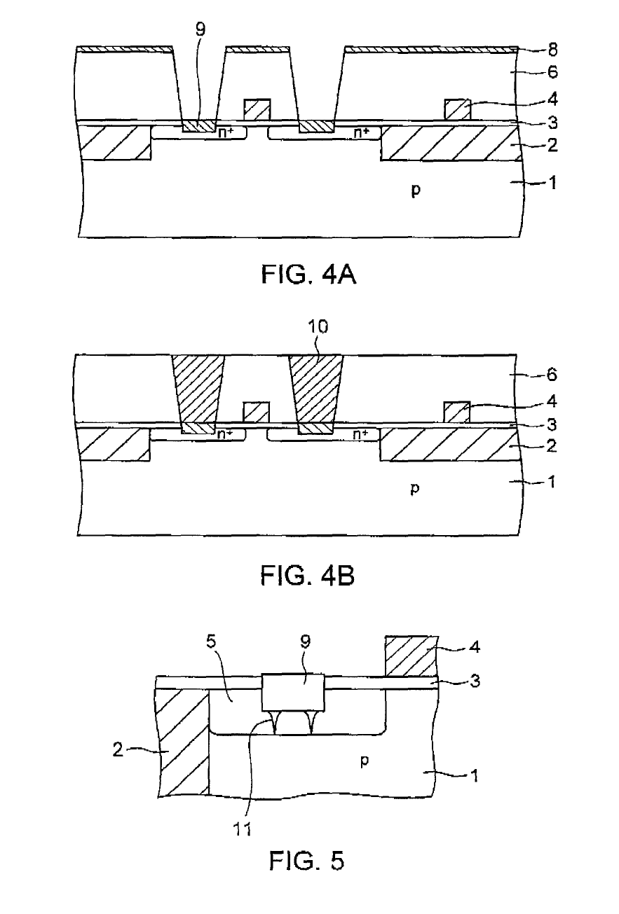

FIGS. 2A through 2F are sectional views showing on the process-by-process basis the method of manufacturing the semiconductor device in a second embodiment of the present invention.

At first, as shown in FIG. 2A, an element isolation region 202 is provided on a p-type silicon substrate 201 by the STI method, etc., . . . and a gate oxide film 203 is provided on the whole by the thermal oxidation method. Polysilicon is then deposited on this gate oxide film 203 by the CVD method, and a gate electrode 204 of a transistor is formed by patterning using the photolithography. Thereafter, an n-type diffused layer 205 is formed in self-alignment with the gate electrode 204 to a depth of, e.g., 100 nm by the ion implantation of impurity such as phosphorus, arsenic and so on.

Next, as shown in FIG. 2B, an inter-layer insulating layer 206 composed of BPSG on the order of, e.g., 700 nm is deposited by use of the CVD method, etc. Thereafter, the inter-layer insulating layer 206 is , etched to such an extent that the diffused layer 104 gets exposed by the RIE method as well as by the photolithography process, thereby forming a contact hole 207 down to the diffused layer 205.

Next, as shown in FIG. 2C, the barrier metal such as Ti is deposited by use of the sputtering method, etc., thereby providing a barrier metal layer 208 having a thickness of 20 nm.

Subsequently, a thin silicon film 209 composed of, e.g., polysilicon or amorphous silicon is deposited up to a thickness of 22.5 nm by the sputtering method, etc.

Next, the thermal treatment is executed at a temperature of, e.g., 600° C., the barrier metal 208 reacts on silicon contained in the diffused layer 205 and the thin silicon film 209 brought into contact with the barrier metal 208, with the result that a silicide layer 210 composed of TiSi is provided (FIG. 2E).

When generating TiSi, the consumption is done at Ti-to-Si thickness ratio of 1:2.27, and hence the thin silicon film 209 of 22.5 nm is consumed on the upper portion of the barrier metal layer 208, and the p-type silicon substrate 201 of 22.5 nm is consumed under the barrier metal layer 208. Accordingly, the silicide layer 210 is formed down to a depth of 22.5 nm from the surface of the p-type silicon substrate 201. In other words, silicon for forming the silicide layer is extracted both from the diffused layer and from the thin silicon film, and therefore a quantity of suicide formed on the side of the diffused layer is by far smaller than in the prior art.

On the other hand, a thickness of the barrier metal on the inter-layer insulating layer 206 is 20 nm, while the thin silicon film 209 is 22.5 nm thick, and the non-reacted barrier metal 208 might be left. There is, however, no problem because this non-reacted barrier metal 208 is removed in a process afterward.

Finally, as shown in FIG. 2F, for example, tungsten W is deposited up to a thickness of 400 nm on the whole by the CVD method , etc., to fill the contact hole 7 with tungsten w, and further the surface is completely flattened by the CMP method, etc., thereby providing a W plug 211.

In the thus formed contact, the lowest portion of the silicide layer that is provided on the bottom of the contact is lower than the surface of the silicon substrate, and a distance from the surface of the silicon substrate from the surface of the silicon substrate down to the lowest portion of the silicide layer formed on the bottom of the contact, is equal to or smaller than ½ the thickness of the silicide layer provided on the bottom of the contact. Accordingly, the distance from the interface between the diffused layer and the silicon substrate to the silicide layer can be kept long, and it is therefore possible to prevent the junction leakage of the diffused layer due to the dispersion in the thickness of the silicide layer and to the formation of the locally deep silicide layer called the spike.

Further, according to the method in the second embodiment, barrier metal and the thin silicon film are sequentially deposited on the diffused layer exposed after forming the contact hole down to the diffused layer, and the suicide layer is provided by effecting the thermal treatment thereafter. Silicon needed for forming silicide is extracted also from the thin silicon film, the bottom surface of silicide is not in close proximity to the interface between the diffused layer and the silicon substrate, and the sufficiently long distance can be kept. It is therefore feasible to prevent the junction leakage of the diffused layer due to the dispersion in the thickness of the silicide layer and to the formation of the locally deep silicide layer called the spike.

In each of the embodiments discussed above, the thin silicon film formed before and after providing the barrier metal may contain any one of elements such as B. P, As, Sb and In. Namely, P, As, Sb are contained in the n-type diffused layer and B and In are contained in the p-type diffused layer, whereby the thin silicon film of the same conductivity type as that of the diffused layer can be provided. It is also possible to effectively prevent the impurity in the diffused layer from being absorbed by the silicide layer.

Moreover, the barrier metal material can be selected from a range of Ti, Zr, Hf, V, Nb, Ta, Cr, Mo, W, Fe, Co, Ni, Pd and Pt, and when using these materials, the silicide layer stable to silicon can be formed.

What is claimed is:

1. A semiconductor device comprising:
a diffused layer provided on a surface portion of a silicon substrate;
an insulating layer provided on said diffused layer and formed with a contact hole at a portion provided with a contact; and
a silicide layer provided within said contact hole as a bottom portion of said contact so as to come into contact with said diffused layer, said silicide layer having its bottom surface being flush with or higher than the surface of said silicon substrate.

2. A semiconductor device according to claim 1, wherein said silicide layer is a silicide layer of any one of Ti, Zr, Hf, V, Nb, Ta, Cr, Mo, W, Fe, Co, Ni, Pd and Pt.

3. A semiconductor device comprising:
a diffused layer provided on a surface portion of a silicon substrate;
an insulating layer provided on said diffused layer and formed with a contact hole at a portion provided with a contact; and
a silicide layer provided within said contact hole as a bottom portion of said contact so as to come into contact with said diffused layer, said silicide layer having its bottom surface being lower than the surface of said silicon substrate,
wherein a distance from the surface of said silicon substrate to the bottom surface of said silicide layer is equal to or smaller than ½ a thickness of said silicide layer provided as the bottom portion of said contact.

4. A semiconductor device according to claim 3, wherein said silicide layer is a silicide layer of any one of Ti, Zr, Ef, V, Nb, Ta, Cr, Mo, W, Fe, Co, Ni, Pd and Pt.

5. A semiconductor device manufacturing method comprising:
providing a thin oxide layer and a gate on the surface of a silicon substrate;
providing a diffused layer service as a source/drain on the surface of said silicon substrate;
depositing an insulating layer on the whole and forming a contact hole in said insulating layer and said thin oxide layer so that said diffused layer is exposed;
depositing a thin silicon film on the whole;
depositing a barrier metal on said thin silicon film; and
making said barrier metal react on said thin silicon film by effecting a thermal treatment and thus providing a silicide layer.

6. A semiconductor device manufacturing method according to claim 5, wherein said thin silicon film is deposited up to such a thickness that the bottom surface of said silicide layer provided on the bottom of said contact is flush with or higher than the surface of said silicon substrate.

7. A semiconductor device manufacturing method according to claim 5, wherein said thin silicon film is deposited up to such a thickness that the bottom surface of said suicide layer provided on the bottom of said contact is lower than the surface of said silicon substrate, and
a distance from the surface of said silicon substrate to the bottom surface of said silicide layer provided on the bottom portion of said contact is equal to or smaller than ½ a thickness of said silicide layer provided on the bottom portion of said contact.

8. A semiconductor device manufacturing method according to claim 5, wherein said thin silicon film is any one of polycrystalline silicon and amorphous silicon.

9. A semiconductor device manufacturing method according to claim 5, wherein said thin silicon film contains any one of element such as Br P, AS, Sb and In.

10. A semiconductor device manufacturing method comprising:
providing a thin oxide layer and a gate on the surface of a silicon substrate;
providing a diffused layer service as a source/drain on the surface of said silicon substrate;
depositing a barrier metal on the whole;
depositing a thin silicon film on said barrier metal; and
making said barrier metal react on said thin silicon film by effecting a thermal treatment and thus providing a silicide layer.

11. A semiconductor device manufacturing method according to claim 10, wherein said thin silicon film is deposited up to such a thickness that the bottom surface of said silicide layer provided on the bottom of said contact is lower than the surface of said silicon substrate, and
a distance from the surface of said silicon substrate to the bottom surface of said silicide layer provided on the bottom portion of said contact is equal to or smaller than ½ a thickness of said silicide layer provided on the bottom portion of said contact.

12. A semiconductor device manufacturing method according to claim 10, wherein said thin silicon film is any one of polycrystalline silicon and amorphous silicon.

13. A semiconductor device manufacturing method according to claim 10, wherein said thin silicon film contains any one of elements such as B, P, AS, Sb and In.

14. A semiconductor device manufacturing method according to claim 10, wherein said barrier metal is any one of Ti, Zr, Hf, V, Nb, Ta, Cr, Mo, W, Fe, Co, Ni, Pd and Pt.
